(19) United States
(12) Patent Application Publication
(10) Pub. No.: US 2008/0069371 A1
(43) Pub. Date: Mar. 20, 2008

(54) Hands free system for vehicle

(75) Inventor: Toshihiro Hosoi, Nagoya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/900,891

(22) Filed: Sep. 13, 2007

(30) Foreign Application Priority Data
Sep. 15, 2006 (JP) 2006-250982

(51) Int. Cl. H04B 1/00; H03G 3/20

(52) U.S. Cl. 381/86; 381/110

(57) ABSTRACT

A hands free system includes: a hands free device on a vehicle; a center device disposed outside of the vehicle; and voice and data circuits. Both of the voice and data circuits are simultaneously coupled between the hands free device and the center device. The hands free device includes a microphone for inputting a voice of a passenger, and transmits a voice signal to the center device through the voice circuit. The center device receives the voice signal, and determines a parameter in relation to voice quality of the voice such that the voice quality is disposed within a predetermined range. The center device transmits the parameter to the hands free device through the data circuit. The hands free device memorizes the parameter so as to transmit the voice in accordance with the parameter.

### CROSS REFERENCE TO RELATED APPLICATION

This application is based on Japanese Patent Application No. 2006-250982 filed on Sep. 15, 2006, the disclosure of which is incorporated herein by reference.

### FIELD OF THE INVENTION

The present invention relates to a hands free system for a vehicle.

### BACKGROUND OF THE INVENTION

A hands free system for a vehicle is mounted on the vehicle. The system has a difficulty that a person cannot communicate with another person through the hands free system under a condition that is preliminarily set by default when the system is replaced to another vehicle, when a cell phone to be connected is changed, or when a user to use the system is switched to another person. Center equipment is disposed on a network side. In the center equipment, an optimum parameter is preliminarily registered in accordance with individual vehicle information. When certain vehicle information is outputted from the vehicle, and inputted into the equipment, the optimum parameter corresponding to the received vehicle information is selected among multiple parameters. The selected optimum parameter is outputted to the hands free system. This system and equipment are disclosed in JP-A-2003-283645.

In the above system and the equipment, it is capable for setting the optimum parameter in view of the vehicle. However, it is difficult to set the optimum parameter in view of voice quality of an individual person because communication through the hands free system is much affected by the voice quality such as male voice or female voice and high voice or low voice.

Thus, it is required for the hands free system to set the optimum parameter in accordance with the voice quality of each person so that the system provides excellent hands free communication having good sound quality.

### SUMMARY OF THE INVENTION

In view of the above-described problem, it is an object of the present disclosure to provide a hands free system for a vehicle.

According to an aspect of the present disclosure, a hands free system for a vehicle includes: a hands free device mounted on the vehicle; a center device disposed in a predetermined place, which is outside of the vehicle; a voice circuit; and a data circuit. Both of the voice circuit and the data circuit are simultaneously coupled between the hands free device and the center device. The hands free device includes a microphone for inputting a voice of a passenger in the vehicle. The hands free device transmits a voice signal to the center device through the voice circuit, the voice signal corresponding to the voice inputted from the microphone. The center device receives the voice signal, and determines a parameter in relation to voice quality of the voice in such a manner that the voice quality is disposed within a predetermined range. The center device transmits the parameter to the hands free device through the data circuit. The hands free device memorizes the parameter so as to transmit the voice inputted from the microphone in accordance with the parameter.

The above system provides hands free communication having excellent voice quality.

### BRIEF DESCRIPTION OF THE DRAWINGS

The above and other objects, features and advantages of the present invention will become more apparent from the following detailed description made with reference to the accompanying drawings. In the drawings:

FIG. 1 is a block diagram showing a hands free system; and

FIG. 2 is a flow chart showing a process executed in the system.

### DETAILED DESCRIPTION OF THE PREFERRED EMBODIMENTS

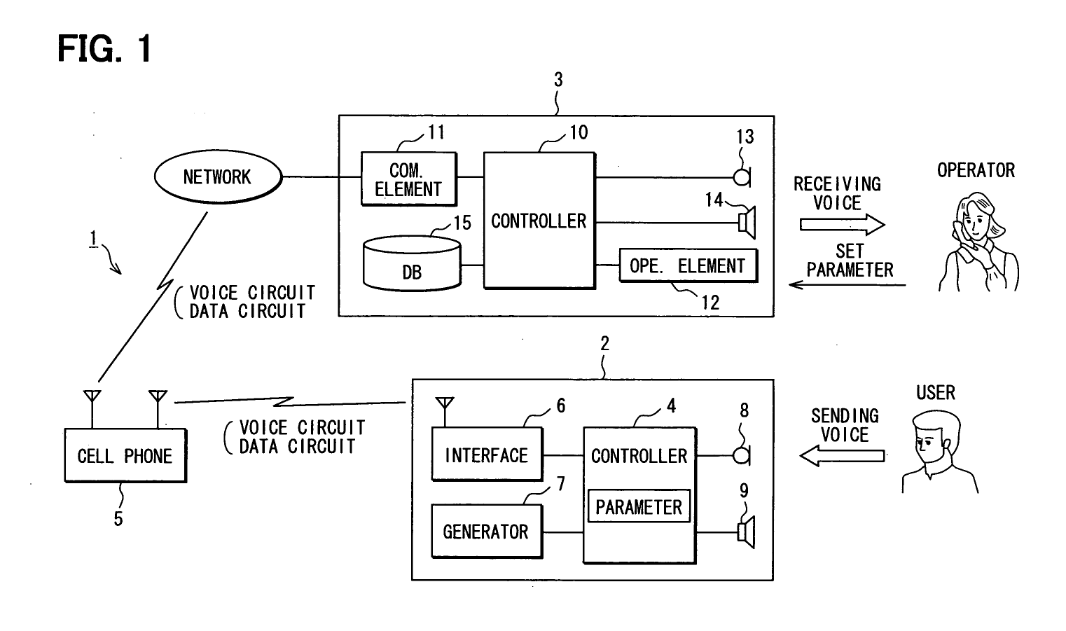

FIG. 1 shows a whole construction of a hands free system 1. The hands free system 1 includes an in-vehicle hands free device 2 mounted on a vehicle and a center device 3 arranged on a network side.

The hands free device 2 includes a control unit 4, a BT (i.e., Bluetooth) communication interface 6, a test signal generator 7, a microphone 8, and a speaker 9. The control unit 4 controls operation of the whole hands free device 2. The BT communication interface 6 communicates between the device 2 and a cell phone 5 by using a Bluetooth (i.e., BT) communication method, and the cell phone 5 has a BT communication function. The test signal generator 7 generates a test signal. The microphone 8 inputs a voice from a user (e.g., a passenger in the vehicle) as a sending voice. The speaker 9 outputs a voice received from the center device 3 as a receiving voice through a network such as a cell phone network. The control unit 4 has various parameters such as sending voice volume, noise cancel volume, voice SW (i.e., sweep) suppression volume, voice SW suppression time, sending voice detection level, and receiving voice detection level.

The center device 3 includes a control unit 10, a communication element 11, an operation element 12, a microphone 13, a speaker 14, and a sound database 15. The control unit 10 controls operation of the whole center device 3. An operator operates the operation element 12. A voice outputted from the operator is inputted in the microphone 13 as a sending voice. A voice received from the hands free device 2 through the network is outputted by the speaker 14 as a receiving voice.

The cell phone 5 is capable of connecting to the center device 3 with both of a voice circuit and a data circuit at the same time. Further, the cell phone 5 is capable of connecting to the hands free device 2 with both of the voice circuit and the data circuit at the same time. Thus, when the user operates the hands free device 2 to send a certain voice, both of the voice circuit and the data circuit are simultaneously connected between the hands free system 2 and the cell phone 5. Further, both of the voice circuit and the data circuit are simultaneously connected between the cell phone 5 and the center device 3. Thus, the user and the operator keep conversation with performing data communication between the user and the operator.

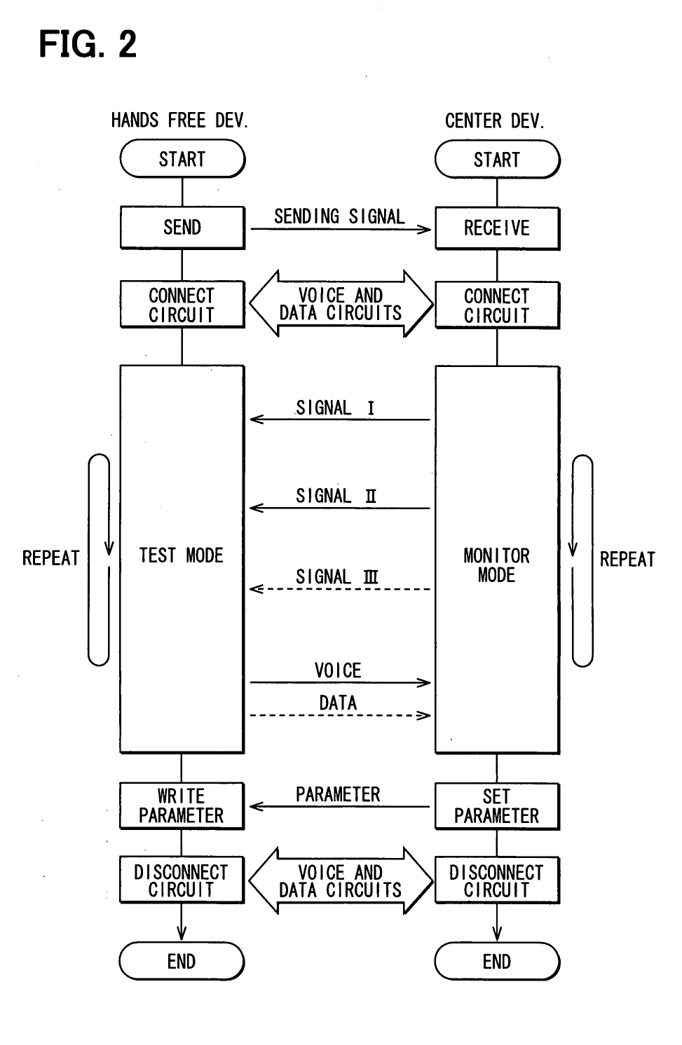

Process of the system 1 is explained with reference to FIG. 2. When the user operates the device 2 to send the sending voice, the hands free device 2 sends a sending signal to the center device 3. The center device 3 receives the sending signal from the hands free device 2. The voice circuit and the data circuit are connected between the hands free device 2 and the center device 3. The hands free device 2 switches from a sending mode to a test mode. The center device 3 switches from a receiving mode to a monitor mode.

After the center device 3 switches to the monitor mode, the operator sounds a voice such as “please park the vehicle at a quiet place” or “please switch off the air conditioner.” The voice is inputted in the microphone 13 as a voice signal I. The inputted voice, i.e., the voice signal I, is transmitted from the center device 3 to the hands free device 2 through the voice circuit. The hands free device 2 receives the voice signal I from the center device 3, and outputs the received signal from the speaker 9 as a received voice. Thus, the user can hear the voice from the operator, and performs a certain action according to the operator's request. For example, the user parks his vehicle at a quiet place when he drives the vehicle, or the user switches off the air conditioner when the air conditioner works.

After that, the operator sounds a voice such as “please speak the following sentence” or “please turn up the receiving voice volume.”, The voice is inputted in the microphone 13 as a voice signal II. The inputted voice, i.e., the voice signal II, is transmitted from the center device 3 to the hands free device 2 through the voice circuit. The hands free device 2 receives the voice signal II from the center device 3, and outputs the received signal from the speaker 9 as a received voice. Thus, the user can hear the voice from the operator, and performs a certain action according to the operator's request. For example, the user speaks a certain sentence, or the user turns up the volume.

Simultaneously, the center device 3 sends a data signal III to the hands free device 2 through the data circuit. The data signal III is, for example, a test noise signal or a sending voice volume sweep signal. The hands free device 2 receives the signal from the center device 3. The hands free device 2 changes various conditions according to the received signal.

When the user sounds a voice according to the operator's instruction, the voice is inputted in the microphone 8 as a sending voice signal. The inputted voice, i.e., the sending voice signal, is transmitted from the hands free device 2 to the center device 3 through the voice circuit. Further, the hands free device 2 detects a sound quality of the voice from the user, and transmits a detected data to the center device 3 through the data circuit. The center device 3 receives the sending voice signal from the hands free device 2, and receives the detected data. The center device 3 processes and analyzes the sending voice signal and the detected data so that a parameter is determined so as to satisfy the voice quality of the sending voice within a predetermined level.

In this case, the parameter may be determined by the operator in such a manner that the sending voice from the hands free device 2 is outputted from the speaker 14, and the operator directly hear the sending voice from the hands free device 2. Alternatively, the sending voice from the hands free device 2 may be digitized, and a digitized sending voice may be compared with a threshold value, which is preliminarily defined, so that a parameter is determined. The sound database 15 in the center device 3 memorizes the determined parameter.

The center device 3 repeats the above steps for certain times, and an optimum parameter is finally determined. The optimum parameter is transmitted from the center device 3 to the hands free device 2 through the data circuit. The hands free device 2 receives a signal corresponding to the optimum parameter, and writes the optimum parameter therein. Since the optimum parameter is memorized in the hands free device 2, the voice signal inputted from the microphone 8 is transmitted according to the optimum parameter.

In the above hands free system 1, the voice circuit and the data circuit are connected simultaneously between the hands free device 2 and the center device 3. The center device 3 receives the voice signal from the hands free device 2, the voice signal corresponding to the voice sounded by the user, and, at the same time, the center device 3 determines the optimum parameter to satisfy the voice quality from the hands free device 2 within a predetermined level. The hands free device 2 memorizes the optimum parameter received from the center device 3. Since the optimum parameter is memorized in the hands free device 2, the hands free device 2 transmits the voice signal corresponding to the voice inputted from the microphone 8 based on the optimum parameter. Thus, the optimum parameter is determined by the voice quality of the user, and the hands free system 1 provides high quality hands free communication having excellent voice quality.

Further, the voice requested by the operator through the center device 3 and inputted into the microphone 8 is transmitted as a sending voice to the center device 3 on the voice circuit. Accordingly, an appropriate parameter is determined in view of an individual voice quality of the user under the same sending voice. Therefore, the system 1 performs hands free communication having excellent sound quality.

Further, since the sound database 15 memorizes the parameter in relation to the voice quality of the sending voice, the parameter may be used for another application program.

Although short range radio communication between the hands free device 2 and the cell phone 5 is performed by the BT communication method, the communication may be performed by another method as long as the voice circuit and the data circuit are simultaneously connected between the hands free device 2 and the cell phone 5.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A hands free system for a vehicle comprising:
a hands free device mounted on the vehicle;
a center device disposed in a predetermined place, which is outside of the vehicle;
a voice circuit; and
a data circuit, wherein
both of the voice circuit and the data circuit are simultaneously coupled between the hands free device and the center device,
the hands free device includes a microphone for inputting a voice of a passenger in the vehicle,
the hands free device transmits a voice signal to the center device through the voice circuit, the voice signal corresponding to the voice inputted from the microphone,
the center device receives the voice signal, and determines a parameter in relation to voice quality of the voice in such a manner that the voice quality is disposed within a predetermined range,
the center device transmits the parameter to the hands free device through the data circuit, and
the hands free device memorizes the parameter so as to transmit the voice inputted from the microphone in accordance with the parameter.

2. The system according to claim 1, wherein
the center device instructs a condition for transmitting the voice signal from the hands free device to the center device so that the voice of the passenger is inputted from the microphone according to an instruction of the center device, and that the voice signal is transmitted to the center device according to the instruction.

3. The system according to claim 1, wherein the center device includes a database for memorizing the parameter.

4. The system according to claim 3, wherein
the center device further includes a speaker and a microphone,
the speaker outputs a sound corresponding to the received voice signal from the hands free device,
the microphone inputs a voice of an operator,
the center device transmits a voice signal to the hands free device through the voice circuit, the voice signal corresponding to the voice of the operator.

5. The system according to claim 4, wherein
the hands free device receives the voice signal from the center device,
the hands free device further includes a speaker for outputting a sound corresponding to the received voice signal from the enter device.

6. The system according to claim 1, further comprising:
a cell phone for communicating with the hands free device and the center device, wherein
the cell phone and the hands free device are coupled with the voice circuit and the data circuit, and
the cell phone and the center device are coupled with the voice circuit and the data circuit.

7. The system according to claim 6, wherein
the center device transmits an instruction for setting a condition to transmit the voice signal from the hands free device to the center device,
the hands free device receives the instruction from the center device, and
the hands free device further includes a speaker for outputting a voice instruction corresponding to the received instruction.

8. The system according to claim 7, wherein
the hands free device further includes a Bluetooth communication interface,
the cell phone includes a Bluetooth communication element,
the cell phone and the hands free device are coupled with each other through the Bluetooth communication interface and the Bluetooth communication element, and
the parameter includes at least one of a sending voice volume, a noise cancel volume, a voice sweep suppression volume, a voice sweep suppression time, a sending voice detection level, and a receiving voice detection level.
